(19) United States
(12) Patent Application Publication
(10) Pub. No.: US 2026/0271469 A1
(43) Pub. Date: Sep. 10, 2026

(54) LIGHT-EMITTING ASSEMBLY AND DISPLAY PANEL

(71) Applicants: Beijing BOE Technology Development Co., Ltd., Beijing (CN); BOE Technology Group Co., Ltd., Beijing (CN)

(72) Inventor: Dejiang ZHAO, Beijing (CN)

(21) Appl. No.: 18/839,831

(22) PCT Filed: Oct. 30, 2023
(86) PCT No.: PCT/CN2023/127817

§ 371 Date: Aug. 20, 2024

(51) Int. Cl. H10H 29/855; H10H 29/49; H10H 29/85; H10H 29/851; H10H 29/856

(52) U.S. Cl. CPC H10H 29/8552; H10H 29/49; H10H 29/8515; H10H 29/8517; H10H 29/856

(57) ABSTRACT

The present disclosure discloses a light-emitting assembly. The light-emitting assembly includes a base substrate, a color conversion layer and a light-emitting unit that are disposed on a first surface of the base substrate, and the light-emitting assembly also includes a light-shielding structure for absorbing light. The light-dimming portion provided on at least one of the first surface and second surface can change the propagation direction of the light.

### CROSS-REFERENCE TO RELATED APPLICATIONS

The present disclosure is a U.S. national phase application based on PCT/CN2023/127817, filed on Oct. 30, 2023, the content of which is herein incorporated by reference in its entirety.

### TECHNICAL FIELD

The present disclosure relates to the field of display technologies, and in particular, relates to a light-emitting assembly and a display panel.

### BACKGROUND

A display panel includes a display backplane and a plurality of light-emitting assemblies connected to the display backplane, wherein the display backplane provides a drive signal for the light-emitting assemblies to cause the light-emitting assemblies to emit light, thereby realizing a display.

### SUMMARY

The present disclosure provides a light-emitting assembly and a display panel. The technical solutions are as follows.

In one aspect, a light-emitting assembly is provided. The light-emitting assembly includes:
a base substrate having a first surface and a second surface;
a color conversion layer disposed on the first surface of the base substrate;
a light-emitting unit disposed on a side of the color conversion layer away from the base substrate, wherein the light-emitting unit emits light for exiting the second surface of the base substrate after passing through the color conversion layer; and
a light-shielding structure having a light-shielding region and a plurality of first hollowed-out regions, wherein an orthographic projection of each of the first hollowed-out regions on the base substrate is at least partially overlapped with a light-emitting region of the light-emitting unit, and the first hollowed-out regions is used for the light emitted from the light-emitting unit to transmit, and the light-shielding structure is configured to absorb light irradiating to the light-shielding region;
wherein at least one of the first surface and the second surface is provided with a light-dimming portion configured to change a propagation direction of light.

In some embodiments, the light-dimming portion includes a light-extraction grating;
wherein an orthographic projection of the light-extraction grating on the base substrate is at least partially overlapped with an orthographic projection of the light-shielding region on the base substrate, the light-extraction grating is configured to transmit the light emitted from the light-emitting unit, and the light-shielding structure is capable of absorbing light transmitted from the light-extraction grating.

In some embodiments, the light-shielding structure is disposed between the first surface of the base substrate and the light-emitting unit, and the light-extraction grating is disposed between the first surface of the base substrate and the light-shielding structure; and the light-dimming portion further includes a reflective layer;
wherein the reflective layer is disposed on the second surface of the base substrate, and an orthographic projection of the reflective layer on the base substrate is at least partially overlapped with the orthographic projection of the light-shielding region on the base substrate, and the reflective layer is configured to reflect light irradiated to the reflective layer to the light-extraction grating.

In some embodiments, the light-shielding structure includes a first light-shielding portion disposed between the first surface of the base substrate and the light-emitting unit, and a second light-shielding portion disposed on the second surface of the base substrate, wherein an orthographic projection of the second light-shielding portion on the base substrate covers an orthographic projection of the first light-shielding portion on the base substrate; and.
the light-extraction grating is disposed between the second surface of the base substrate and the second light-shielding portion, and the light emitted from the light-emitting unit is absorbed by the second light-shielding portion after transmitting the light-extraction grating.

In some embodiments, the light-emitting assembly includes a plurality of light-emitting units, wherein the light-emitting units emit light of a same color, and colors emitted from the plurality of light-emitting units after passing through the color conversion layer include a first color, a second color, and a third color that are different from each other; and the light-extraction grating includes:
a first grating, configured to transmit light of the first color, wherein an orthographic projection of the first grating on the base substrate surrounds a light-emitting region of a light-emitting unit of the first color;
a second grating, configured to transmit light of the second color, wherein an orthographic projection of the second grating on the base substrate surrounds a light-emitting region of a second light-emitting unit of the second color; and
a third grating, configured to transmit light of the third color, wherein an orthographic projection of the third grating on the base substrate surrounds a light-emitting region of a third light-emitting unit of the third color;

In some embodiments, colors emitted from the plurality of light-emitting units are all of the third color; and the light-extraction grating further includes a fourth grating;
wherein an orthographic projection of the fourth grating on the base substrate surrounds light-emitting regions of the plurality of light-emitting units, and the fourth grating is configured to transmit light of the third color.

In some embodiments, a groove structure is arranged in at least one of the first surface and the second surface;
wherein the light-dimming portion is disposed in the groove structure, the light-dimming portion is configured to reflect light irradiated to the light-dimming portion to a region where an orthographic projection of the light-emitting region of the light-emitting unit is disposed on the base substrate, or the light-dimming portion is configured to absorb the light irradiated to the light-dimming portion; and the groove structure surrounds the light-emitting region of the light-emitting unit.

In some embodiments, the light-emitting assembly includes a plurality of light-emitting units, wherein the light-emitting units emit light of a same color, and colors emitted from the plurality of light-emitting units after passing through the color conversion layer include: a first color, a second color, and a third color that are different from each other; the groove structure includes:
a plurality of first annular grooves, wherein each of the first annular grooves surrounds a light-emitting region of one of the light-emitting units; and
a second annular groove, wherein the second annular groove surrounds light-emitting regions of the plurality of light-emitting units; and
the light-dimming portion includes:
a plurality of first light-dimming portion, wherein each of the first light-dimming portions is disposed in one of the first annular grooves, a material of the first light-dimming portion is a reflective material or a light-absorbing material; and
a second light-dimming portion, wherein the second light-dimming portion is disposed in the second annular groove, and a material of the second light-dimming portion is a light-absorbing material.

In some embodiments, the second annular groove includes a plurality of sub-annular grooves, wherein a depth of each of the sub-annular grooves is negatively correlated with a distance between the sub-annular groove and the light-emitting unit; and
the second light-dimming portion includes a plurality of sub-light-dimming portions, wherein each of the sub-light-dimming portions is disposed in one of the sub-annular grooves.

In some embodiments, the plurality of sub-annular grooves includes a plurality of first sub-annular grooves and a plurality of second sub-annular grooves;
wherein the plurality of first sub-annular grooves are disposed in the first surface, the plurality of second sub-annular grooves are disposed in the second surface, the plurality of first sub-annular grooves and the plurality of second sub-annular grooves are staggered, and a sum of a depth of one of the first sub-annular grooves and a depth of one of the second sub-annular grooves is less than a thickness of the base substrate; and
the second light-dimming portion includes a plurality of first sub-dimming portions and a plurality of second sub-dimming portions, wherein each of the first sub-dimming portions is disposed in one of the first sub-annular grooves, and each of the second sub-dimming portions is disposed in one of the second sub-annular grooves.

In some embodiments, both the first annular grooves and the second annular groove are continuous grooves; or,
each of the first annular grooves includes a plurality of first dotted grooves, an arrangement of the plurality of first dotted grooves being annular; and
the second annular groove includes a plurality of second dotted grooves, and an arrangement of the plurality of second dotted grooves being annular.

In some embodiments, the light-emitting assembly further includes a light-absorbing portion, wherein the light-absorbing portion at least covers a side edge of the base substrate, and a material of the light-absorbing portion is a light-absorbing material.

In some embodiments, the light-emitting assembly further includes a color film layer disposed between the base substrate and the color conversion layer;
wherein the color film layer includes a plurality of color film patterns, the color conversion layer includes a plurality of color conversion patterns and a plurality of light-transmitting patterns, wherein each of the plurality of color film patterns corresponds to one target pattern in the plurality of color conversion patterns and the plurality of light-transmitting patterns; and
the light-emitting assembly further includes a retaining wall structure; wherein the retaining wall structure has a plurality of second hollowed-out regions, wherein the plurality of second hollowed-out regions are in one-to-one correspondence with the plurality of first hollowed-out regions, and an orthographic projection of each of the second hollowed-out regions on the base substrate is at least partially overlapped with an orthographic projection of a corresponding first hollowed-out region on the base substrate;
wherein each of the color film patterns is disposed in one of the first hollowed-out regions, and the target pattern corresponding to the color film pattern is disposed in the second hollowed-out region corresponding to the first hollowed-out region.

In some embodiments, the light-emitting unit includes a first electrode, a second electrode, and a light-emitting layer connected to the first electrode and the second electrode; and the light-emitting assembly further includes a driving unit disposed on a side of a plurality of light-emitting units away from the base substrate;
wherein the driving unit includes a third electrode, a fourth electrode, and a driving circuit, wherein both the third electrode and the fourth electrode are connected to the driving circuit, and the third electrode is connected to the first electrode, and the fourth electrode is connected to the second electrode.

In another aspect, a display panel is provided. The display panel includes a display backplane, and a plurality of light-emitting assemblies as described in the above aspect that are disposed on a side of the display backplane and arranged in an array;
wherein the display backplane is configured to provide a drive signal for the light-emitting assemblies to drive the light-emitting assemblies to emit light.

### BRIEF DESCRIPTION OF DRAWINGS

For clearer description of the technical solutions according to the embodiments of the present disclosure, the following briefly introduces the accompanying drawings required for describing the embodiments. Apparently, the accompanying drawings in the following description show merely some embodiments of the present disclosure, and persons of ordinary skill in the art may still derive other drawings from these accompanying drawings without creative efforts.

FIG. 1 is a partial cross-sectional diagram of a light-emitting assembly according to some embodiments of the present disclosure;

FIG. 2 is a schematic diagram of a light path of a light-emitting assembly in the prior art;

FIG. 3 is a schematic diagram of a light path of a light-emitting assembly according to some embodiments of the present disclosure;

FIG. 4 is a partial cross-sectional diagram of another light-emitting assembly according to some embodiments of the present disclosure;

FIG. 5 is a schematic diagram of a light path of another light-emitting assembly according to some embodiments of the present disclosure;

FIG. 6 is a top view of a light-emitting unit and a light-extraction grating according to some embodiments of the present disclosure;

FIG. 7 is a partial cross-sectional diagram of yet another light-emitting assembly according to some embodiments of the present disclosure;

FIG. 8 is a top view of another light-emitting assembly, a groove structure, and a light-dimming portion according to some embodiments of the present disclosure;

FIG. 9 is a schematic diagram of a light path of yet another light-emitting assembly according to some embodiments of the present disclosure;

FIG. 10 is a top view of another light-emitting assembly, a groove structure, and a light-dimming portion according to some embodiments of the present disclosure;

FIG. 11 is a partial cross-sectional diagram of still another light-emitting assembly according to some embodiments of the present disclosure;

FIG. 12 is a top view of yet another light-emitting assembly, a groove structure, and a light-dimming portion according to some embodiments of the present disclosure;

FIG. 13 is a schematic diagram of a light path of still another light-emitting assembly according to some embodiments of the present disclosure;

FIG. 14 is a partial cross-sectional diagram of still another light-emitting assembly according to some embodiments of the present disclosure;

FIG. 15 is a schematic diagram of a light path of still another light-emitting assembly according to some embodiments of the present disclosure;

FIG. 16 is a partial cross-sectional diagram of still another light-emitting assembly according to some embodiments of the present disclosure;

FIG. 17 is a schematic diagram of a light path of still another light-emitting assembly according to some embodiments of the present disclosure;

FIG. 18 is a partial cross-sectional diagram of a base substrate according to some embodiments of the present disclosure;

FIG. 19 is a partial cross-sectional diagram of another base substrate according to some embodiments of the present disclosure;

FIG. 20 is a partial cross-sectional diagram of yet another light-emitting assembly according to some embodiments of the present disclosure;

FIG. 21 is a partial cross-sectional diagram of a light-emitting unit according to some embodiments of the present disclosure;

FIG. 22 is a partial cross-sectional diagram of yet another light-emitting assembly according to some embodiments of the present disclosure;

FIG. 23 is a partial cross-sectional diagram of a display panel according to some embodiments of the present disclosure; and

FIG. 24 is a top view of a display panel according to some embodiments of the present disclosure.

### DETAILED DESCRIPTION

For clearer descriptions of the objectives, technical solutions, and advantages of the present disclosure, embodiments of the present disclosure are described in detail hereinafter with reference to the accompanying drawings.

In the related art, a light-emitting assembly includes a substrate, and a light-emitting unit and a driving unit that are disposed on a side of the base substrate. The light-emitting unit and the driving unit are connected to enable the driving unit to provide a drive signal for the light-emitting unit, which in turn enables the light-emitting unit to emit light under the driving of the driving unit.

However, light emitted from the light-emitting unit is prone to be continuously fully reflected within the substrate to form an optical waveguide, and the presence of the optical waveguide will lead to light leakage from the edge position of the light-emitting assembly, resulting in poor display quality.

In the prior art, light emitted from a light-emitting unit included in a light-emitting assembly forms an optical waveguide after entering a base substrate, and the presence of the optical waveguide will lead to light leakage from the edge position of the light-emitting assembly, resulting in poor display quality.

Exemplarily, the light-emitting assembly includes a base substrate, a color conversion layer disposed on a side of the base substrate, a bonding layer, and a light-emitting unit. The light (e.g., blue light) emitted from the light-emitting unit forms an optical waveguide within the bonding layer, and enters the substrate substrate through the cut channel at the outer edge, forming a blue light leakage. Light emitted from the light-emitting unit passes through the color conversion layer (which can be transformed into red light or green light), enters the base substrate, and forms an optical waveguide within the substrate, which in turn generates red light leakage and green light leakage. The bonding layer is a common film layer for bonding the light-emitting unit and the color conversion layer.

The condition for the formation of an optical waveguide is that the base substrate has two optical surfaces, and when light is conducted within the base substrate and the total reflection condition is satisfied, total reflection can occur on both optical surfaces. The total reflection effect of the two optical surfaces causes the light to be bound within the base substrate in a certain direction.

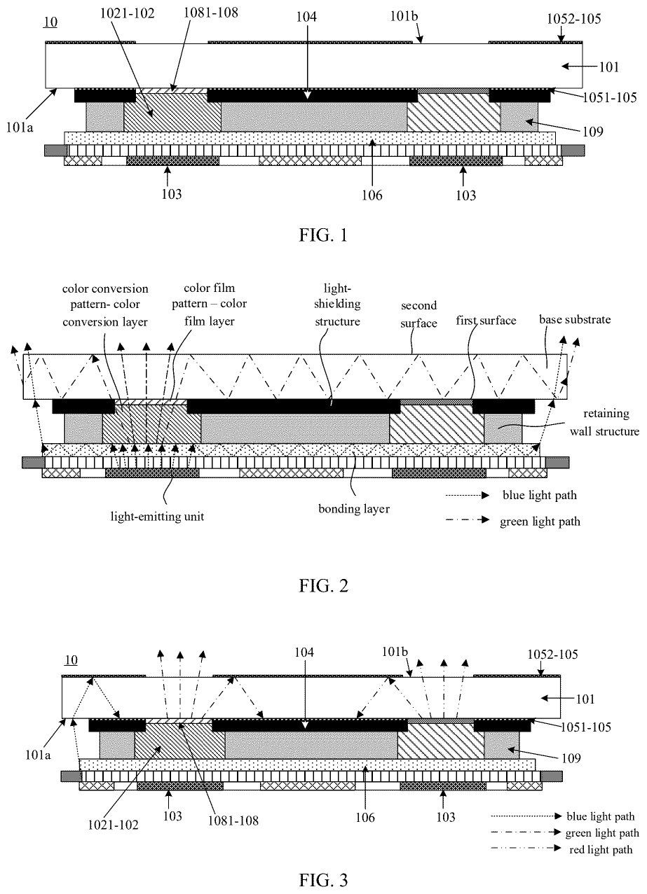

FIG. 1 is a schematic structural diagram of a light-emitting assembly 10 according to some embodiments of the present disclosure. Referring to FIG. 1, the light-emitting assembly 10 includes a base substrate 101, a color conversion 102, a light-emitting unit 103, and a light-shielding portion 104.

In the embodiments of the present disclosure, the base substrate 101 has a first surface 101a and a second surface 101b. The color conversion layer 102 is disposed on the first surface 101a of the base substrate 101, and the light-emitting unit 103 is disposed on a side of the color conversion layer 102 away from the base substrate 101. The light emitted from light-emitting unit 103 is used to exit from the second surface 101b of the base substrate 101 after passing through the color conversion layer 102. That is, the first surface 101a of the base substrate 101 may be a carrier surface for carrying the device, and the second surface 101b may be a light-emitting surface.

Referring to FIG. 1, the light-shielding structure 104 has a light-shielding portion and a plurality of first hollowed-out regions. An orthographic projection of each of the first hollowed-out regions on the base substrate 101 is at least partially overlapped with a light-emitting region of the light-emitting unit 103. The first hollowed-out region is configured for the light emitted from the light-emitting unit 103 to transmit. There may be a portion of the light emitted from the light-emitting unit 103 that will be irradiated to a light-shielding region of the light-shielding structure 104, and in turn, the light-shielding region may absorb this portion of the light to avoid light leakage.

Further, referring to FIG. 1, at least one of the first surface and the second surface of the base substrate is provided with a light-dimming portion 105. As the light-dimming portion 105 disrupts the surface characteristics of the base substrate 101, the light does not form an optical waveguide by multiple total reflections within the base substrate 101, but rather the propagation direction is changed. That is, by providing the light-dimming portion 105 on at least one of the first surface 101a and the second surface 101b, the propagation direction of the light can be changed.

Optionally, referring to FIG. 2, in the case where the light-dimming portion 105 is not provided, the light will be reflected from the second surface 101b to the first surface 101a by the second surface 101b after irradiation to the second surface 101b, and then be reflected from the first surface 101a to the second surface 101b, and so on and so forth to form an optical waveguide, which will result in crosstalk or light leakage. Only the blue and the light green light paths are shown in FIG. 2, not the red light path (which is similar to the green light path). Referring to FIG. 3, in the case where the light-dimming portion 105 is provided, the light will be reflected from the second surface 101b to the first surface 101a by the second surface 101b after irradiation to the second surface 101b, and the light that would otherwise be reflected on the first surface 101a is not reflected, but is absorbed by the light-shielding structure 104 after emitting the first surface 101a.

In the embodiments of this present disclosure, as the light-dimming portion 105 is provided, the light can be avoided from forming an optical waveguide within the base substrate 101, and then the light can be avoided from exiting from the edge position due to the presence of the optical waveguide, and thus light leakage and crosstalk can be avoided, and the display effect can be ensured.

In summary, the embodiments of the present disclosure provide a light-emitting assembly, the light-emitting assembly includes a base substrate, a color conversion layer and a light-emitting unit that are disposed on a first surface of the base substrate. The light-emitting assembly further includes a light-shielding structure used for absorbing the light. At least one of the first surface and second surface of the base substrate is provided with a light-dimming portion configured to change a propagation direction of the light, thereby avoiding the formation of an optical waveguide of the light within the base substrate, further avoiding the light leakage of the light exiting from the edge of the light-emitting assembly, and ensuring the display effect.

In a first optional implementation, referring to FIG. 1, it can be seen that the light-dimming portion 105 includes a light-extraction grating 1051. An orthographic projection of the light-extraction grating 1051 on the base substrate 101 is at least partially overlapped with an orthographic projection of the light-shielding portion on the base substrate 101. The light-extraction grating 1051 is configured to transmit the light emitted from the light-emitting unit 103, and the light-shielding structure 104 is capable of absorbing light transmitted from the light-extraction grating 1051.

The setting of the light-dimming portion 105 as the light-extraction grating is mainly based on the principle of grating diffraction, whereby the grating (having a periodic characteristic) is capable of causing the light of different wavelengths to change the propagation direction accordingly and regularly as they pass through them. The main function of the light-extraction grating 1051 is to be used to extract light of a specific wavelength. In the the present disclosure, the light-dimming portion 105 including the light-extraction grating 1051 is illustrated in the following two embodiments.

In a first embodiment, referring to FIG. 1, the light-shielding structure 104 is disposed between the first surface 101a of the base substrate 101 and the light-emitting unit 103, and the light-extraction grating 1051 is disposed between the first surface 101a of the base substrate 101 and the light-shielding structure 104. The light-dimming portion 105 further includes a reflective layer 1052.

The reflective layer 1052 is disposed on the second surface 101b of the base substrate 101, an orthographic projection of the reflective layer 1052 on the base substrate 101 is at least partially overlapped with the orthographic projection of the light-shielding region on the base substrate 101. The reflective layer 1052 is configured to reflect light irradiated to the reflective layer 1052 to the light-extraction grating 1051. Optionally, the reflective layer 1052 is a distributed bragg reflector (DBR).

The purpose of providing the reflective layer 1052 on the second surface 101b of the base substrate 101 is to avoid light leakage caused by light exiting directly from the location of the light-shielding region. Referring to FIG. 3, the reflective layer 1052 reflects the light and can be extracted directly by the light-extraction grating 1051 and absorbed by the light-shielding structure 104 on the side of the light-extraction grating 1051 away from the base substrate 101. As a result, the light can be avoided from forming an optical waveguide within the base substrate 101, and edge light leakage can be avoided.

Optionally, the reflective layer 1052 includes two materials with different refractive indices arranged in a sequentially overlapping manner. The thickness of each layer of material may be equal to ¼ of the wavelength of the light. Exemplarily, both materials may be organic, or, one of the two materials may be organic and the other may be inorganic.

The preparation method of the organic material can be nanoimprinting, and the preparation method of the inorganic material can be high-precision exposure machine exposure etching. As the preparation of the organic material is simpler, and the toughness of the organic material is better than that of the inorganic material, the preferred two materials are both organic materials. Exemplarily, the two materials are epoxy resin material and acrylic resin material.

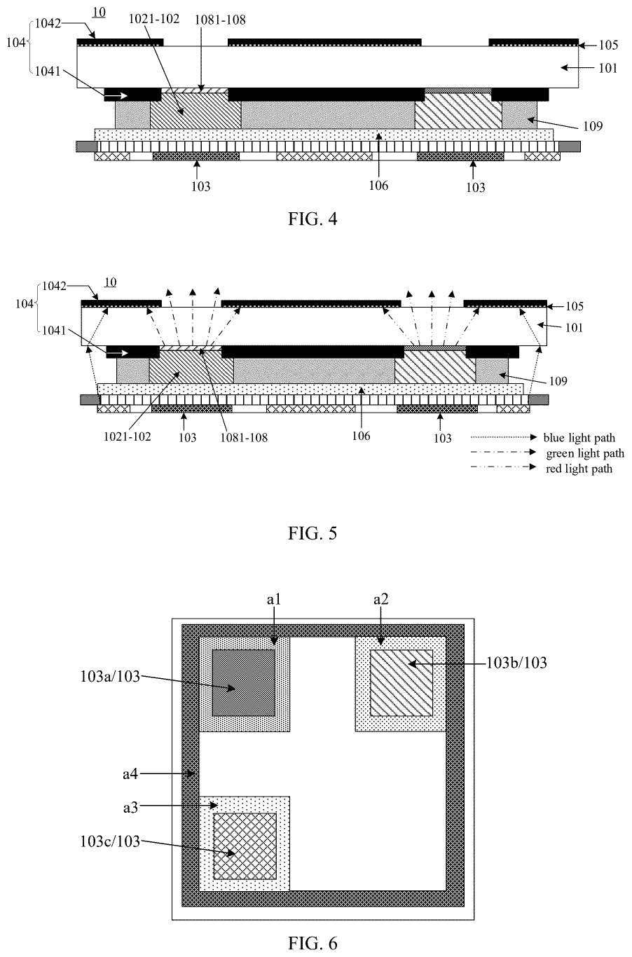

In the second embodiment, referring to FIG. 4, the light-shielding structure 104 includes a first light-shielding portion 1041 disposed between the first surface 101a of the base substrate 10 and light-emitting unit 103, and a second light-shielding portion 1042 disposed on the second surface 101b of the base substrate 101. An orthographic projection of the second light-shielding portion 1042 on the base substrate 101 covers an orthographic projection of the first light-shielding portion 1041 on the base substrate 101.

Optionally, the edge of the orthographic projection of the second light-shielding portion 1042 on the base substrate 101 may extend beyond the edge of the orthographic projection of the first light-shielding portion 1041 on the base substrate 101, for example, in a range of 3 micrometers (μm) to 5 μm. In this way, light leakage due to light exiting at an abnormal angle can be better avoided. In addition, the thickness of the second light-shielding portion 1042 may range from 0.8 μm to 1.2 μm.

In addition, the light-extraction grating 1051 is disposed between the second surface 101b of the base substrate 101 and the second light-shielding portion 1042, and the light emitted from the light-emitting unit 103 is absorbed by the second light-shielding portion 1042 after transmitting the light-extraction grating 1051.

Referring to FIG. 5, in the case that the light-extraction grating 1051 is provided, the light will not be reflected by the second surface 101b after irradiation to the second surface 101b, but will be extracted via the light-extraction grating 1051 and absorbed by the second light-shielding portion 1042. As a result, crosstalk can be avoided by the light exiting directly from the position where the light-shielding region is located, and light leakage can be avoided by the light exiting from the edge position after the light waveguide is formed in the base substrate 101, such that the display effect is ensured.

In both the first embodiment and the second embodiment, the light-emitting assembly 10 includes a plurality of light-emitting units 103. The light-emitting unit 103 emits the light of the same color, and the colors emitted from the plurality of light-emitting units after passing through the color conversion layer 102 include a first color, a second color, and a third color. The first color, the second color, and the third color are different from each other. Exemplarily, the first color is red (R), the second color is green (G), and the third color is blue (B). Exemplarily, the light emitted from the plurality of light-emitting units is all of a third color (blue).

As the light emitted from the plurality of light emitting units 103 included in the light-emitting assembly 10 can be transformed into a plurality of different colors after passing through the color conversion layer 102, and the wavelengths of the different colors of light are different, the light-extraction grating 1051 needs to include different gratings to enable the extraction of light of different wavelengths.

Optionally, referring to FIG. 6, light-extraction grating 1051 includes a first grating al, a second grating a2, and a third grating a3. The first grating al is configured to transmit light of the first color, an orthographic projection of the first grating al on the base substrate 101 surrounds a light-emitting region of a first light-emitting unit 103a in the plurality of light-emitting units 103, and a color of light emitted from the first light-emitting unit 103a after passing through the color conversion layer 102 is the first color. The second grating a2 is configured to transmit light of the second color, an orthographic projection of the second grating a2 on the base substrate 101 surrounds a light-emitting region of a second light-emitting unit 103b in the plurality of light-emitting units 103, and a color of light emitted from the second light-emitting unit 103b after passing through the color conversion layer 102 is the second color. The third grating a3 is configured to transmit light of the third color, an orthographic projection of the third grating a3 on the base substrate 101 surrounds a light-emitting region of a third light-emitting unit 103c in the plurality of light-emitting units 103, and a color of the light emitted from the third light-emitting 103c unit after passing through the color conversion layer 102 is the third color.

Exemplarily, the first grating al may be referred to as a red light grating, and the period of the red light grating may be from 430 to 470 with a duty cycle of 0.5. The second grating a2 may be referred to as a green grating, and the period of the green grating may be from 400 to 430 with a duty cycle of 0.5. The third grating a3 may be referred to as a blue light grating, and the period of the blue light grating may be from 360 to 390 with a duty cycle of 0.5. The period of the grating represents the number of grating slits provided within a length range of one um. The duty cycle of the grating is a ratio of a slit region to a non-slit region.

Referring to FIG. 1, the light-emitting assembly 10 further includes a bonding layer 106 disposed between the color conversion layer 102 and the plurality of light-emitting unit 103, the bonding layer 106 serves to bond the color conversion layer 102 and the plurality of light-emitting unit 103. The material of the bonding layer 106 may be epoxy resin with a special adhesive, with the thickness ranging from 3 μm to 10 μm, and a transmittance rate greater than or equal to 90%.

Referring to FIG. 6, the color of the light emitted from the light-emitting units 103 is a third color (blue, with a wavelength range of 450 nm to 470 nm), and the light emitted from the light-emitting units 103 may be reflected multiple times within the bonding layer 106 to form an optical waveguide, which in turn may result in light leakage as the light exits from the edges of the bonding layer 106. Thus, thee light-extraction grating 1051 may further include a fourth grating a4, an orthographic projection of the fourth grating a4 on the base substrate 101 surrounds light-emitting regions of the plurality of light-emitting units 103, and the fourth grating a4 is configured to transmit the light of the third color. Optionally, the fourth light grating a4 may be referred to as a blue light grating.

That is, in the embodiments of the present disclosure, a grating of the corresponding color may be provided around each color light-emitting unit 103, and a blue light grating may be provided around the plurality of light-emitting units 103.

Optionally, for the red light grating and the green light grating, the width of the grating can be 20 to 30 times the wavelength of the light, ensuring that the light is completely extracted. Exemplarily, the width of the red light grating is 20 to 30 times the wavelength of the red light, ensuring that the red light is completely extracted. The width of the green grating is 20 to 30 times the wavelength of the green light, ensuring that the green light is completely extracted.

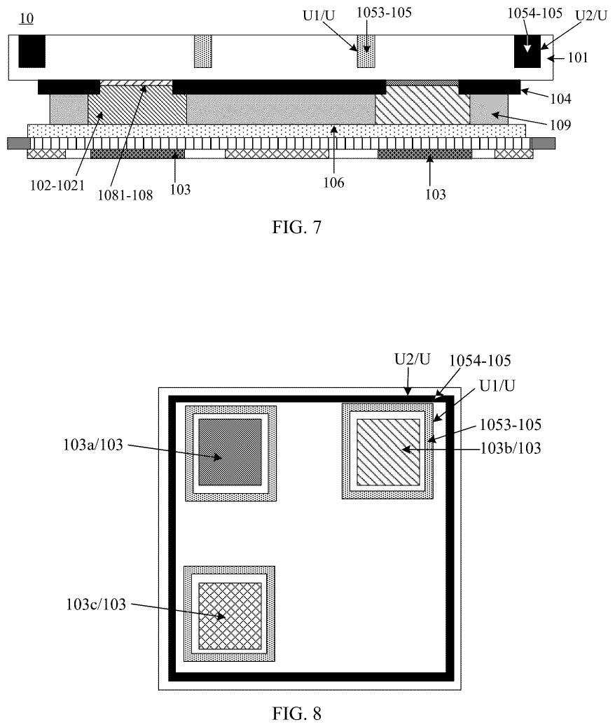

In a second optional implementation, referring to FIG. 7, a groove structure U is arranged in at least one of the first surface 101a and the second surface 101b. The light-dimming portion 105 is disposed in the groove structure U, the light-dimming portion 105 is configured to reflect light irradiated to the light-dimming portion 105 to a region where an orthographic projection of the light-emitting region of the light-emitting unit 103 is disposed on the base substrate 101. Alternatively, the light-dimming portion 105 is configured to absorb the light irradiated to the light-dimming portion 105. The groove structure U surrounds the light-emitting region of light-emitting unit 103.

As the light-dimming portion 105 is capable of reflecting or absorbing light and is disposed within the groove structure U on the surface of the base substrate 101, it is possible to change the surface characteristics of the base substrate 101, and thus the propagation direction of the light.

Optionally, in the case that the material of the light-dimming portion 105 is a light-absorbing material, the light-dimming portion 105 may be used for absorbing light and thus avoiding light leakage. In the case that the material of the light-dimming portion 105 is a reflective material, the light-dimming portion 105 may be used for reflecting the light to increase the positive light output of the light-emitting assembly 10.

In the embodiments of the present disclosure, an arrangement in which the groove structure U is provided on the surface of the base substrate 101 and the light-dimming portion 105 is provided within the groove structure U is illustrated in the following six embodiments. In addition, in the following embodiments, the light-emitting assembly 10 includes a plurality of light-emitting units 103. The light-emitting units 103 emit light of the same color, and the color emitted from the plurality of light-emitting units 103 after passing through the color conversion layer 102 includes a first color, a second color, and a third color. The first color, the second color, and the third color are different from each other. Exemplarily, the first color is red, the second color is green, and the third color is blue. Exemplarily, the light emitted from the plurality of light-emitting units 103 is all of the third color (blue).

In a first embodiment, referring to FIG. 7 and FIG. 8, the groove structure U includes a plurality of first annular groove U1 and a second annular groove U2. Each of the first annular grooves U1 surrounds a light-emitting region of one light-emitting unit 103, and the second annular groove U2 surrounds light-emitting regions of the plurality of light-emitting unit 103. Correspondingly, the light-dimming portion 105 includes a plurality of first light-dimming portion 1053 and second light-dimming portion 1054. each of the first light-dimming portions 1053 is disposed in one of the first annular grooves U1, a material of the first light-dimming portion 1053 is a reflective material or a light-absorbing material. The second light-dimming portion 1054 is disposed in the second annular groove U2, and a material of the second light-dimming portion 1054 is a light-absorbing material.

For the peripheral region of the light-emitting region of each light-emitting unit 103, in the case that the material of the first light-dimming portion 1053 is the reflective material, the reflective material can reflect the light to the region where the orthographic projection of the light-emitting region of the pixel unit on the base substrate 101 is located. In the cases that the material of the first light-dimming portion 1053 is the light-absorbing material (e.g., a black material), the light-absorbing material can absorb the light directly, avoiding light leakage and crosstalk.

Optionally, the reflective material may be a scattering-type resin material, and the light will be scattered and ejected by the scattering-type material upon irradiation to the scattering-type material. Although the embodiment of the reflective material has a high optical utilization rate relative to the embodiment of the light-absorbing material, there is a certain risk of light leakage in the embodiment of the reflective material, as the light may enter into the base substrate 101.

For the peripheral region of the light-emitting regions of the plurality of light-emitting units 103, as this region is relatively far away from the light-emitting regions of the light-emitting units 103, in the case that the material of the second light-dimming portion 1054 is set to be the reflective material, not only may it result in the light not being able to increase the positive light output, but also may result in the light reflecting multiple times within the base substrate 101 to form an optical waveguide. Thus, for the peripheral region of the light-emitting regions of the plurality of light-emitting units 103, the material of the second light-dimming portion 1054 may be the light-absorbing material, such that the light is directly absorbed by the light-absorbing material to avoid light leakage.

In the embodiment of the present disclosure, referring to FIG. 7, the plurality of first annular grooves U1 and the second annular groove U2 included in the groove structure U are all disposed on the second surface 101b of the base substrate 101. In addition, the plurality of first annular grooves U1 and the second annular groove U2 included in the groove structure U may also be disposed on the first surface 101a of the base substrate 101. The embodiment of the present disclosure does not limit this.

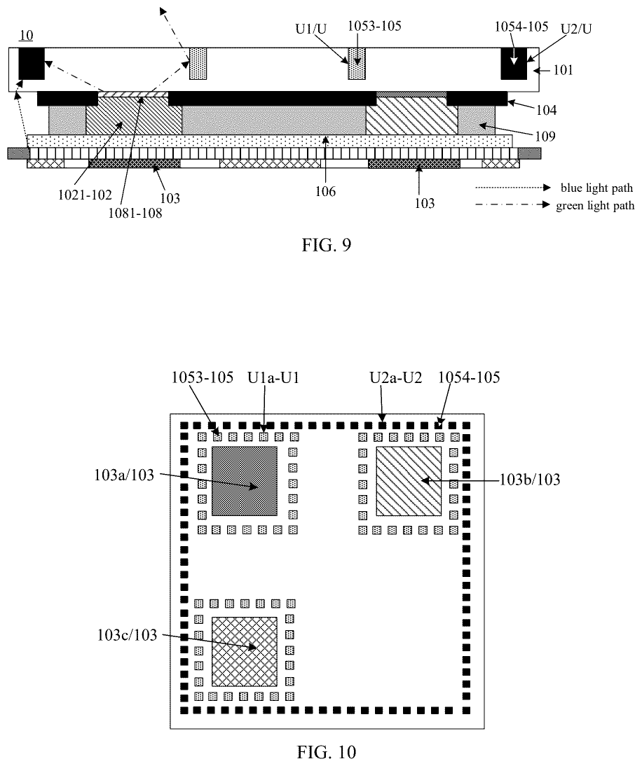

In the first embodiment, referring to FIG. 9, taking the material of the first light-dimming portion 1053 as a reflective material and the material of the second light-dimming portion 1054 as a light-absorbing material as an example. The light irradiated to the first light-dimming portion 1053 can be reflected by the first light-dimming portion 1053 to increase the positive light output, and the light irradiated to the second light-dimming portion 1054 can be absorbed by the second light-dimming portion 1054. As a result, light leakage can be avoided by the light exiting directly from the position where the light-shielding region is located, and light leakage can be avoided by the light exiting from the edge position after the optical waveguide is formed in the base substrate 101, such that the display effect is ensured.

As shown in FIG. 7 and FIG. 8, both the first annular grooves Ul and the second annular groove U2 are continuous grooves. Correspondingly, both the first light-dimming portions 1053 and the second light-dimming portion 1054 are continuous light-dimming portions.

In a second embodiment, referring to FIG. 10, the groove structure U includes a plurality of first annular groove Ul and a second annular groove U2. Each of the first annular grooves U1 includes a plurality of first dotted grooves U1a. An arrangement of the plurality of first dotted grooves is annular, i.e., surrounds the light-emitting region of the first light-emitting unit 103. The second annular groove U2 includes a plurality of second dotted grooves U2a. An arrangement of the plurality of second dotted grooves U2a is annular, i.e., surrounds the light-emitting regions of the plurality of light-emitting units 103.

Correspondingly, the first light-dimming portion 1053 includes a plurality of first dotted light-dimming portions, and each of the first dotted light-dimming portions is disposed in one of the first dotted grooves U1a. The second light-dimming portion 1054 includes a plurality of second dotted light-dimming portions, and each of the second dotted light-dimming portions is disposed in one of the second dotted grooves U2a. In addition, related descriptions of the materials for the first light-dimming portion 1053 and the second light-dimming portion 1054 can be found in the first embodiment as described above, and the embodiment of the present disclosure will not be repeated herein.

The dimensions of the first dotted groove Ula and the second dotted groove U2a range from 6 μm to 15 μm, and the spacing ranges from 3 μm to 5 μm. Moreover, the depth of the first dotted groove U1a and the second dotted groove U2a may be 60% to 80% of the thickness of the base substrate 101. For example, assuming that the thickness of the base substrate 101 is 0.5 mm, the depth of the first dotted groove Ula and the second dotted groove U2a may be 0.3 mm.

Optionally, referring to FIG. 10, the shape of the projections of the first dotted groove Ula and the second dotted groove U2a may be square. In addition, other shapes are possible, such as circles, hexagons, and triangles.

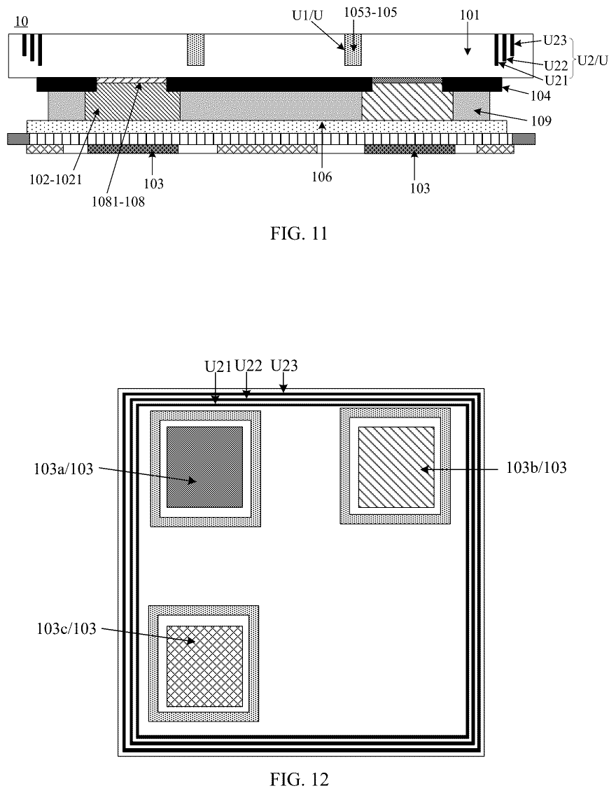

In a third embodiment, referring to FIG. 11 and FIG. 12, the groove structure U includes a plurality of first annular grooves Ul and a second annular groove U2a. Each of the first annular grooves U1 surrounds the light-emitting region of one light-emitting unit 103. The second annular groove U2 includes a plurality of sub-annular grooves (U21, U22, and U2), and the depth of each of the sub-annular grooves is negatively correlated with a distance between the sub-annular groove and the light-emitting unit 103. That is, the depth of the sub-annular groove closer to the light-emitting unit 103 is deeper, and the depth of the sub-annular groove away from the light-emitting unit 103 is shallower.

Exemplarily, referring to FIG. 11, the second annular groove U2 includes a first sub-annular groove U21, a second sub-annular groove U22, and a third sub-annular groove U23 which are arranged sequentially away from the light-emitting unit 103. The depth of the first sub-annular groove U21 is greater than the depth of the second sub-annular groove U22, and the depth of the second sub-annular groove U22 is greater than the depth of the third sub-annular groove U23. In addition, the second sub-annular groove U2 may also include a greater number of sub-annular grooves, and the embodiments of the present disclosure do not limit the number of sub-annular grooves included in the second annular groove U2.

Correspondingly, the light-dimming portion 105 includes a plurality of first light-dimming portion 1053 and a second light-dimming portion 1054. Each of the first light-dimming portions 1053 is disposed in one of the first annular grooves U1, and the material of the first light-dimming portions 1053 is a reflective material or a light-absorbing material. The second light-dimming portion 1054 includes a plurality of sub-dimming portions (not shown in the figure), each of the sub-light-dimming portions is disposed in one sub-annular groove, and the material of each of the sub-dimming portions is a light-absorbing material. In addition, related descriptions of the materials for the first light-dimming portion 1053 and the second light-dimming portion 1054 can be found in the first embodiment as described above, and the embodiment of the present disclosure will not be repeated herein.

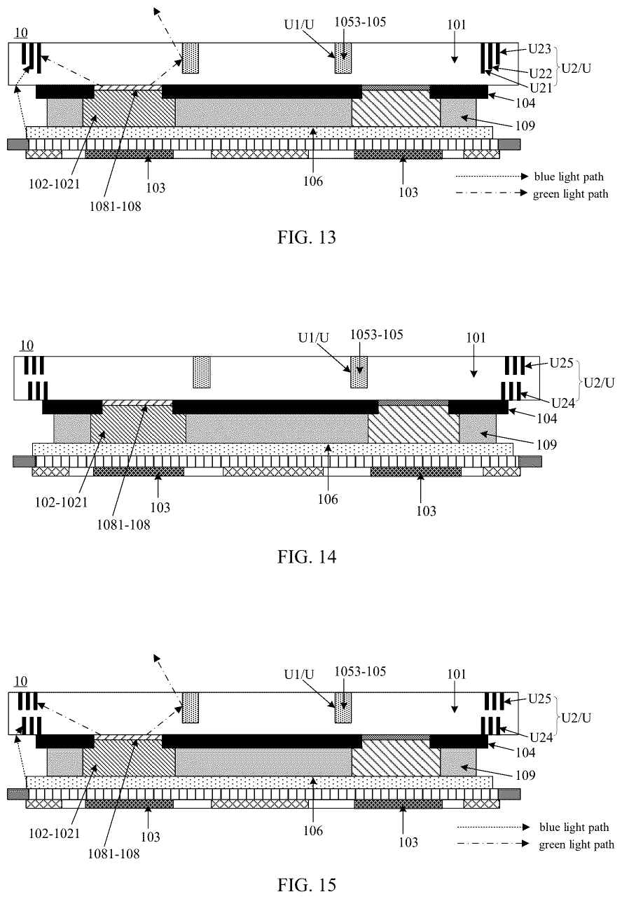

It should be noted that the sub-annular grooves in the third embodiment may be continuous grooves or may include a plurality of dotted grooves. For the third embodiment, referring to FIG. 13, taking the material of the first light-dimming portions 1053 as a reflective material and the material of the second light-dimming portion 1054 as a light-absorbing material as an example. The light irradiated to the first light-dimming portion 1053 can be reflected by the first light-dimming portion 1053 to increase the positive light output, and the light irradiated to the second light-dimming portion 1054 can be absorbed by the second light-dimming portion 1054. As a result, light leakage can be avoided by the light exiting directly from the position where the light-shielding region is located, and light leakage can be avoided by the light exiting from the edge position after the optical waveguide is formed in the base substrate 101, such that the display effect is ensured.

In a fourth embodiment, referring to FIG. 14, the groove structure U includes a plurality of first annular grooves U1 and a second annular groove U2. Each of the first annular grooves U1 surrounds a light-emitting region of one light-emitting unit 103, and the second annular groove U2 includes a plurality of sub-annular grooves. The plurality sub-annular grooves include a plurality of fourth sub-annular grooves U24 and a plurality of fifth sub-annular grooves U25.

The plurality of fourth sub-annular grooves U24 are disposed on the first surface 101a, and the plurality of fifth sub-annular grooves U25 are disposed on the second surface 101b. The plurality of fourth sub-annular grooves U24 and the fifth sub-annular grooves U25 are staggered to absorb light at different positions. Moreover, the sum of the depth of the fourth sub-annular groove U24 and the depth of the fifth sub-annular groove U25 is less than the thickness of the base substrate 101. Thus, it can be avoided that the strength of the base substrate 101 is too much affected due to the arrangement of the grooves. For example, the sum of the depths of the fourth sub-annular groove U24 and the fifth sub-annular groove U25 is equal to 70% of the thickness of the base substrate 101.

Correspondingly, the light-dimming portion 105 includes a plurality of first light-dimming portions 1053 and a second light-dimming portion 1054. Each of the light-dimming portions 1053 is disposed in one of the first annular grooves U1, and the material of the first light-dimming portion is a reflective material or a light-absorbing material. The second light-dimming portion 1054 includes a plurality of first sub-dimming portions and a plurality of second sub-dimming portions (not shown in the figure). Each of the first sub-dimming portions is disposed in one of the fourth sub-annular grooves U24, and each of the second sub-dimming portions is disposed in one of the fifth sub-annular grooves U25. The material of each sub-imming portion is a light-absorbing material, In addition, related descriptions of the materials for the first light-dimming portion 1053 and the second light-dimming portion 1054 can be found in the first embodiment as described above, and the embodiment of the present disclosure will not be repeated herein.

It should be noted that the fourth sub-annular grooves U24 and the fifth sub-annular grooves U25 in the fourth embodiment may be continuous grooves or may include a plurality of dotted grooves. For the fourth embodiment, referring to FIG. 15, taking the material of the first light-dimming portion 1053 as a reflective material and the material of the second light-dimming portion 1054 as a light-absorbing material as an example. The light irradiated to the first light-dimming portion 1053 can be reflected by the first light-dimming portion 1053 to increase the positive light output, and the light irradiated to the second light-dimming portion 1054 can be absorbed by the second light-dimming portion 1054. As a result, light leakage can be avoided by the light exiting directly from the position where the light-shielding region is located, and light leakage can be avoided by the light exiting from the edge position after the optical waveguide is formed in the base substrate 101, such that the display effect is ensured.

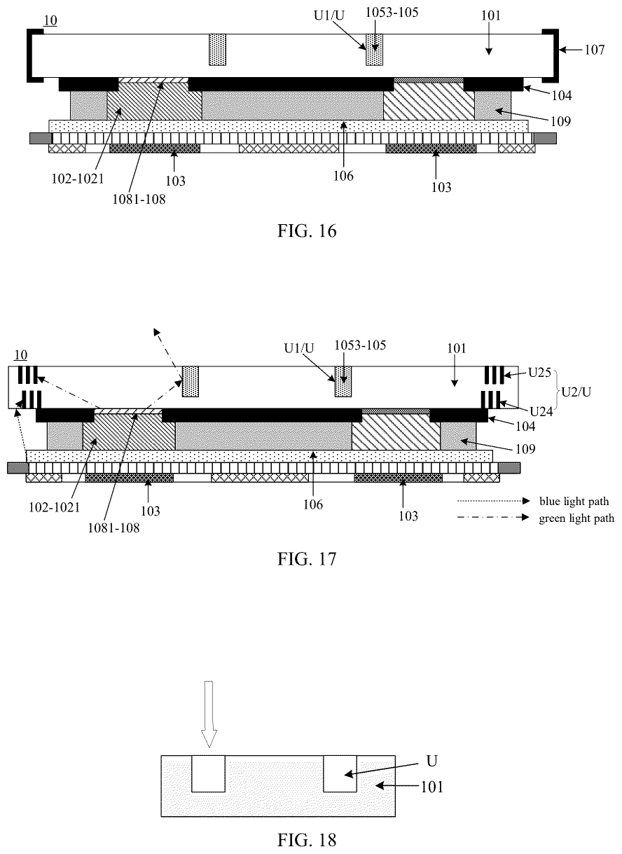

In a fifth embodiment, referring to FIG. 16, the groove structure U includes a plurality of first annular groove U1. Each of the first annular grooves U1 surrounds a light-emitting region of one light-emitting unit 103. Correspondingly, the light-dimming portion 105 includes a plurality of first light-dimming portion 1053. Each of the first light-dimming portions 1053 is disposed in one of the first annular grooves U1, and the material of the first light-dimming portion 1053 is a reflective material or light-absorbing material.

The first annular grooves U1 may be continuous grooves. Correspondingly, the first light-dimming portions 1053 may be continuous light-dimming portions. Alternatively, the first annular groove U1 includes a plurality of first dotted grooves U1a, and an arrangement of the plurality of first dotted grooves Ula is annular.

In the embodiment, referring to FIG. 16, the light-emitting assembly 10 further includes a light-absorbing portion 107. The light-absorbing portion 107 at least covers a side edge of the base substrate 101, and the material of the light-absorbing portion is a light-absorbing material (e.g., a black material). In addition, referring to FIG. 16, the light-absorbing portion 107 may be disposed at one end on the first surface 101a of the base substrate 101 and at another end on the second surface 101b of the base substrate 101, in addition to covering the side edges of the base substrate 101.

The method of preparing the light-absorbing portion 107 may be a side adhesive coating process. The thickness of the light-absorbing portion 107 may range from 0.8 μm to 1 μm.

For the fifth embodiment, referring to FIG. 17, taking the material of the first light-dimming portion 1053 as a reflective material and the material for the second light-dimming portion 1054 as a light-absorbing material as an example. The light irradiated to the first light-dimming portion 1053 can be reflected by the first light-dimming portion 1053 to increase the positive light output, and the light irradiated to the second light-dimming portion 1054 can be absorbed by the second light-dimming portion 1054. As a result, light leakage can be avoided by the light exiting directly from the position where the light-shielding region is located, and light leakage can be avoided by the light exiting from the edge position after the optical waveguide is formed in the base substrate 101, such that the display effect is ensured.

In the fifth embodiment, the groove structure may not include the second annular groove U2 surrounding the light-emitting regions of the plurality of light-emitting units 103, and correspondingly, the light-dimming portion 105 may not include the second light-dimming portion 1054. In this case, the light-absorbing portion 107 may absorb light in the peripheral region of the light-emitting regions of the plurality of light-emitting units 103 to avoid light leakage. Moreover, the groove structure may also include the second annular groove U2 surrounding the light-emitting regions of the plurality of light-emitting units 103, and accordingly, the light-dimming portion may also include the second light-dimming portion 1054. In this case, the light-absorbing portion 107 and the second light-dimming section 1054 may work together to absorb light in the peripheral regions of the light-emitting regions of the plurality of light-emitting units 103.

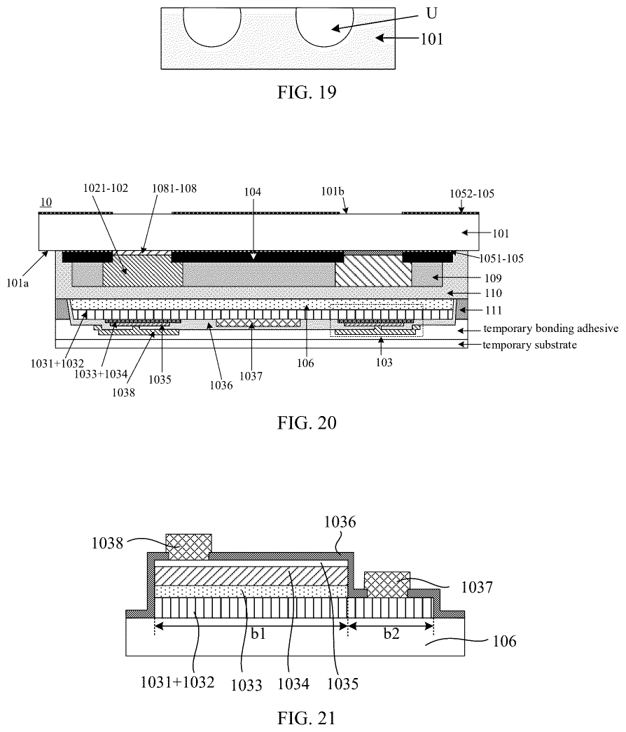

In the second implementation above, the formation of the groove structure U may be achieved in one of the following two ways: referring to FIG. 18, the groove is formed by laser etching and the sidewall of the formed groove is perpendicular to the surface of the base substrate 101; referring to FIG. 19, the groove is formed by wet etching and the sidewall of the formed groove is a curved sidewall.

Optionally, in order to make the light-dimming portion effective, it is necessary to make the total area of the bottom and sidewalls of the groove structure (i.e., the surface area of the groove structure) large enough. For example, in the case that the width of the groove structure U is small, the depth of the groove structure U can be made deeper; and in the case that the width of the groove structure U is large, the depth of the groove structure U can be made shallower.

Exemplarily, in the case that the width of the groove structure U ranges from 20 μm to 30 μm, the depth can be reduced to 5 μm to 10 μm. This is because damaging the surface of the base substrate 101 causes the propagation of light to be changed, and the width of the groove structure U is wide enough to accommodate more than 30 reflected light rays, which is sufficient to absorb all of the light rays.

As for the two embodiments mentioned in the first implementation and the six embodiments in the second implementation, referring to FIG. 1 to 5, FIG. 7, FIG. 9, FIG. 11, and FIG. 13 to 17, the light-emitting assembly further includes a color film layer disposed between the base substrate 101 and the color conversion layer 102.

The color film layer 108 includes a plurality of color film patterns 1081, and the color conversion layer 102 includes a plurality of color conversion patterns 1021 and a plurality of light-transmitting patterns (not shown in the figure). Each of the plurality of color film patterns 1081 corresponds to one target pattern in the plurality of color conversion patterns 1021 and the plurality of light-transmitting patterns. The correspondence may refer to color correspondence.

Exemplarily, the plurality of color film patterns 1081 include red color film patterns, green color film patterns, and blue color film patterns. The plurality of color conversion patterns 1021: red color conversion patterns and green color conversion patterns. The red color film pattern corresponds to the red color conversion pattern, the green color film pattern corresponds to the green color conversion pattern, and the blue color film pattern corresponds to the light-transmitting pattern.

The light-emitting assembly 10 further includes a retaining wall structure 109. The retaining wall structure 109 has a plurality of second hollowed-out regions, and the plurality of second hollowed-out regions are in one-to-one correspondence with the first hollowed-out regions. An orthographic projection of each of the second hollowed-out regions on the base substrate 101 is at least partially overlapped with an orthographic projection of a corresponding first hollowed-out region on the base substrate 101.

Each of the color film patterns 1081 is disposed in one of the first hollowed-out regions, and the target pattern corresponding to the color film pattern 1081 is disposed in the second hollowed-out region corresponding to the first hollowed-out region. The red color film pattern and the red color conversion pattern are respectively disposed in the corresponding first hollowed-out region and the second hollowed-out region. The green color film pattern and the green color conversion pattern are respectively disposed in the corresponding first hollowed-out and second hollowed-out region. The blue color film pattern and the light-transmitting pattern are respectively disposed in the corresponding first hollowed-out region and the second hollowed-out region.

For the first embodiment in the first implementation and the six embodiments in the second implementation, the light-shielding structure 104 may serve as a black matrix (BM) that accommodates the color film patterns 1081. For the second embodiment in the first implementation, the first light-shielding portion 1041 included in the light-shielding structure 104 can serve as the black matrix that accommodates the color film patterns 1081. The thickness of the black matrix ranges from 1.2 μm to 2 μm. The black matrix may have a small amount of flaking at the edge locations of the base substrate 101 due to damage from the subsequent cutting process, which is one reason why light may form an optical waveguide in the base substrate 101.

The thickness of the color film pattern ranges from 1.5 μm to 2 μm. The main function of the red color film pattern and the green color film pattern is to filter the blue light that is not converted by the color conversion pattern 1021 of the color conversion layer 102, and to correct the light that is converted by the color conversion pattern 1021 to improve the color gamut. The main function of the blue color film pattern is to correct the light that has passed through the light-transmitting pattern to improve the color gamut.

The thickness of the retaining wall structure 109 ranges from 5 μm to 15 μm. The material of the retaining wall structure 109 can be resin-based materials with low surface energy (e.g., fluorine-containing acrylic or epoxy resins). To achieve the light-blocking effect, scattering particles are doped therein, which can be silicon oxide (SiO₂) or titanium oxide (TiO₂). Alternatively, the retaining wall structure 109 can also be colored with black dye.

The main function of the color conversion pattern 1021 is to convert the light emitted from the light-emitting layer 1033 of the light-emitting unit 103. The material of the color conversion pattern 1021 can be a cadmium-based material such as cadmium selenide and cadmium sulfide, or it can also be a cadmium-free material such as indium phosphite (InP), chalcogenide and carbon nanopowder. The thickness of the color conversion pattern 1021 ranges from 5 μm to 15 μm, and the color conversion pattern 1021 is in the form of an adhesive material with a solid content ranging from 5% to 30%.

In the embodiments of the present disclosure, referring to FIG. 20, the light-emitting assembly 10 further includes: an encapsulation layer 110 disposed on a side of the retaining wall structure 109 away from the base substrate 101 The encapsulation layer 110 can be used to encapsulate the color conversion layer 102 and the color film layer 108.

The encapsulation layer 110 may be a purely inorganic encapsulation or a mixed organic and inorganic encapsulation. In the case that the encapsulation layer 110 is the inorganic encapsulation, the encapsulation layer 110 may include three or five layers of inorganic material layers, and the material of each inorganic material layer may be silicon nitride (SiNₓ) or silicon oxide (SiO₂). The thickness of each inorganic layer ranges from 100 nm (nanometers) to 500 nm. In the case that the encapsulation layer 110 is the mixed organic and inorganic encapsulation, the encapsulation layer 110 may be a sandwich structure of an inorganic material layer (with a thickness of 1000 nm), an organic material layer (with a thickness ranging from 3 μm to 10 μm), and an inorganic material layer (with a thickness of 100 nm).

In the embodiments of the present disclosure, the light-emitting unit 103 may be a light-emitting unit 103 with an inverted structure. Referring to FIG. 21, the light-emitting unit 103 includes a buffer layer 1031, a first doped layer 1032, a light-emitting layer 1033, a second doped layer 1034, a conductive layer 1035, an insulating layer 1036, a first electrode 1037, and a second electrode 1038. The first doped layer 1032 has a first target region b1 and a second target region b2. The light-emitting layer 1033, the second doped layer 1034, and the first doped layer 1032 are stacked in the first target region b1. The insulating layer 1036 is disposed on a side of the second doped layer 1034 away from the base substrate. The insulating layer 1036 has a first via and a second via, the first via is used to expose a portion of the second target region b2, and the second via is used to expose a portion of the conductive layer 1035. The first electrode 1037 included in the light-emitting unit 103 is connected to the second target region b2 of the first doped layer 1032 through the first via, and the second electrode 1038 included in the light-emitting unit 103 is connected to the conductive layer 1035 through the second via. The first electrode 1037 and the second electrode 1038 can be used to introduce signals, thereby achieving light emission.

The light-emitting region of the light-emitting unit 103 can be the region between the first electrode 1037 and the second electrode 1038. In addition, the orthographic projection of the light-emitting region on the base substrate 101 covers the orthographic projection of the color conversion pattern 1021 on the base substrate 101 and also covers the orthographic projection of the color film pattern 1081 on the base substrate 101.

Optionally, the doping types of the first doped layer 1032 and the second doped layer 1034 are different. For example, the first doped layer 1032 is an N-type doped layer, and the second doped layer 1034 is a P-type doped layer. The first doped layer 1032 can include N-type doped gallium nitride (GaN), and the first doped layer 1032 is denoted as N-GaN. The second doped layer 1034 can include P-type doped gallium nitride (GaN), and the second doped layer 1034 is denoted as P-GaN. Additionally, the material of the buffer layer 1031 can be undoped gallium nitride (GaN). The insulating layer 1036 can be a passivation layer (PVX).

Combining FIG. 20 and FIG. 21, in the case that the light-emitting assembly 10 includes a plurality of light-emitting units 103, the buffer layers 1031 and the first doped layers 1032 of the plurality of light-emitting units 103 can be a shared doped layer. Correspondingly, the first electrode 1037 connected to the first doped layer 1032 can be a common electrode (which may be referred to as a cathode).

Referring to FIG. 20, the light-emitting assembly 10 further includes a dam structure 111, the dam structure 111 can be disposed around the buffer layer 1031 and the first doped layer 1032 of the plurality of light-emitting units 103 for protecting the light-emitting units 103.

Referring to FIG. 20, a temporary base substrate and a temporary bonding adhesive are also shown. The temporary base substrate and the temporary bonding adhesive are intermediate film layers required in the manufacturing process of the light-emitting assembly 10, and there is no such temporary base substrate and temporary bonding adhesive in the final product. For example, before bonding and connecting the light-emitting unit 103 and the driving unit 112, the temporary base substrate and the temporary bonding adhesive are removed.

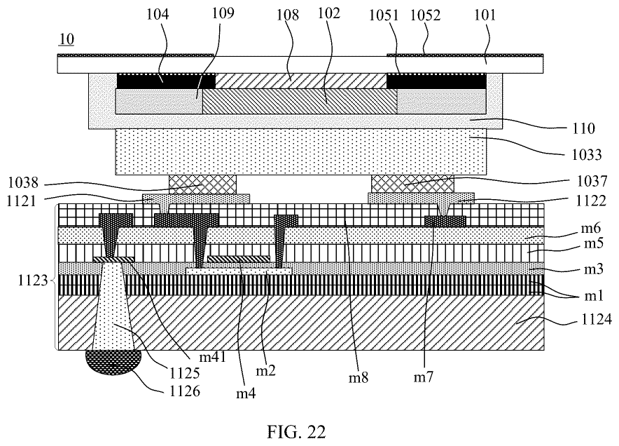

In the embodiments of the present disclosure, referring to FIG. 22, the light-emitting assembly 10 further includes a driving unit 112 disposed on a side of the plurality of light-emitting units 103 away from the base substrate 101. The driving unit 112 includes a third electrode 1121, a fourth electrode 1122, and a driving circuit 1123. Both the third electrode 1121 and the fourth electrode 1122 are electrically connected to the driving circuit 1123, the third electrode 1121 is electrically connected to the first electrode 1037, and the fourth electrode 1122 is electrically connected to the second electrode 1038.

Referring to FIG. 22, the driving unit 112 further includes a substrate 1124, a connection structure 1125, and a pin 1126. The material of the substrate 1124 may be polyimide (PI) and the substrate 1124 may be referred to as a PI substrate. The substrate 1124 has a connection via, and the connection structure 1125 is disposed within the connection via. Moreover, the driving circuit 1123 is disposed on a side of the substrate, the pin 1126 is disposed on a side of the substrate away from the driving circuit 1123, and the pin 1126 and the connection structure 1125 are in contact. The pin 1126 and the driving circuit 1123 are connected through the connection structure 1125, thereby causing the pin 1126 to transmit a drive signal for the driving circuit 1123 through the connection structure 1125.

In embodiments of the present disclosure, the driving circuit 1123 may include a plurality of thin film transistors and at least one storage capacitor. Optionally, the driving circuit 1123 may include seven thin film transistors and one storage capacitor, i.e., the driver circuit 1123 is a 7T1C driving circuit. Alternatively, the driving circuit 1123 may include other numbers of thin film transistors and other numbers of storage capacitors. The embodiments of the present disclosure do not limit the number of thin-film transistors included in the driving circuit 1123, and the number of storage capacitors included.

Each thin film transistor includes a gate, a source, and a drain. The plurality of thin film transistors included in the driving circuit 1123 are interconnected to achieve the light emission of the light-emitting unit 103.

Optionally, the plurality of thin film transistors includes at least a data-writing transistor, and the source of the data-writing transistor is connected to the data line of the display backplane in the display panel. The data line may transmit a data drive signal to the driving circuit 1123 through the data writing transistor.

In the embodiments of the present disclosure, the data writing transistor is connected to the third electrode 1121 of the driving unit 112 through other thin film transistors in the driving circuit 1123, thereby enabling the data line included in the display backplane of the display panel to transmit the data drive signal to the second electrode 1038 of the light-emitting unit 103 through the pin 1126, the connection structure 1125, the driving circuit 1123, and the fourth electrode 1122.

It should be noted that in order to enable the driving unit 112 to drive the light-emitting unit 103 to emit light, a power signal (e.g., a VSS signal) needs to be provided to the first electrode 1037 of the light-emitting unit 103, in addition to the data drive signal provided to the second electrode 1038 of the light-emitting unit 103. Optionally, the power signal provided by the display backplane for a plurality of light-emitting assemblies 10 included in the display panel may be the same, i.e., the plurality light-emitting assemblies 10 may share the first electrode 1037.

Referring to FIG. 22, the driving circuit 1123 includes a buffer layer (buffer+barrier) m1, an active layer (poly) m2, a first gate insulating layer (gate insulator, GI) m3, a first gate layer (gate) m4, a second gate insulating layer m5, a second gate layer (not shown in the figure), an inter-level dielectric layer (ILD) m6, a source-drain layer m7 and a planarization layer (PLN) m8, which are disposed on a side of the base substrate 1124 and are stacked in sequence. The third electrode 1121 and the fourth electrode 1122 included in the driving unit 112 are disposed on a side of the planarization layer m8 away from the base substrate.

The active layer m2 includes a plurality of active patterns corresponding to the plurality of thin-film transistors. Each active pattern includes a source region, a drain region, and a channel region. The source and drain of the thin-film transistor are disposed in the source-drain layer, and the source of the thin-film transistor is connected to the source region, and the drain is connected to the drain region.

The first gate layer m4 includes a plurality of gate patterns corresponding to the plurality of thin-film transistors. The channel region is an overlapping region of the orthographic projection of the gate pattern on the base substrate and the orthographic projection of the active pattern on the base substrate.

Referring to FIG. 22, the first gate layer m4 further includes a gate connection portion m41 connected to the connection structure 1125. The gate connection portion m41 is configured to be connected to the connection structure 1125 and the source of the data writing transistor. In order to connect the connection structure 1125 and the gate connection portion m41, a connection via may also be provided in the buffer layer m1 and the first gate insulating layer m3. In addition, the connection structure 1125 is not only disposed in the connection via of the base substrate 1024, but also in the connection via of the buffer layer ml and the first gate insulating layer m3.

In summary, the embodiments of the present disclosure provide a light-emitting assembly, the light-emitting assembly includes a base substrate, a color conversion layer and a light-emitting unit that are disposed on a first surface of the base substrate. The light-emitting assembly further includes a light-shielding structure used for absorbing the light. At least one of the first surface and second surface of the base substrate is provided with a light-dimming portion configured to change a propagation direction of the light, thereby avoiding the formation of an optical waveguide of the light within the base substrate, further avoiding the light leakage of the light exiting from the edge of the light-emitting assembly, and ensuring the display effect.

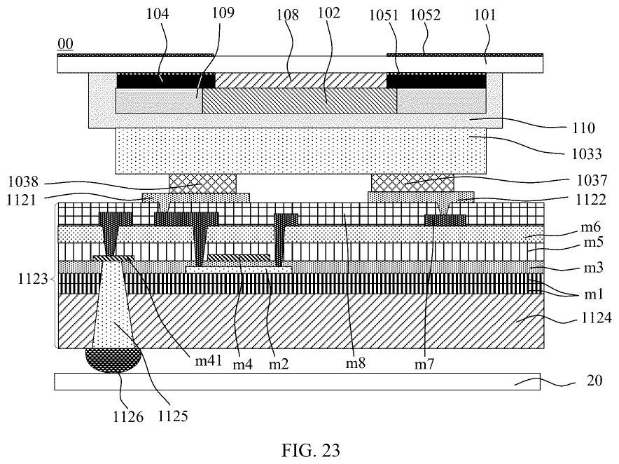

FIG. 23 is a schematic structural diagram of a display panel according to some embodiments of the present disclosure. Referring to FIG. 23, the display panel 00 includes a display backplane 20 and a plurality of light-emitting assemblies 10.

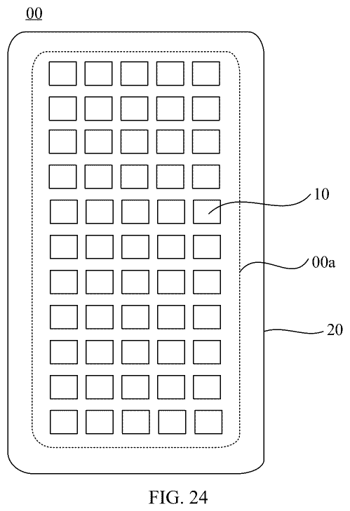

Referring to FIG. 24, the plurality of light-emitting assemblies 10 are disposed in the display region 00a of the display panel 00, and the plurality of light-emitting assemblies 10 are arranged in an array. The display backplane 20 is configured to provide a drive signal for the driving unit 112 in the light-emitting assembly 10, such that the driving unit 112 drives the light-emitting unit 103 to emit light.

As the display panel can have essentially the same technical effects as the light-emitting assembly described in the previous embodiments, the technical effects of the display panel will not be repeated here for brevity purposes.

The terms used in the embodiments section of the present disclosure are only to explain embodiments of the present disclosure and are not intended to limit the present disclosure. Unless otherwise defined, the technical terms or scientific terms used in the embodiments of the present disclosure should have the ordinary meaning understood by a person of ordinary skill in the field to which the present disclosure belongs.

The terms “first,” “second,” “third,” and similar terms used in the specification and claims of the present disclosure do not indicate any order, number, or importance, but are only used to distinguish different components. Similarly, the words like “one” or “a” do not indicate a limitation of quantity, but rather the existence of at least one. Similar terms such as “include” or “comprise” mean that the element or object now preceding “include” or “comprise” cover the element or object appearing after “include” or “comprise” and their equivalents, and do not exclude other elements or objects. Similar terms such as “connect” or “connected” are not limited to physical or mechanical connections, but may include electrical connections, whether direct or indirect. Terms “up,” “down,” “left,” “right,” etc. are only used to indicate relative positional relationships. In the case that the absolute position of the described object changes, the relative positional relationship may also change accordingly.

Described above are merely the exemplary embodiments of the present disclosure, but are not intended to limit the present disclosure. Any modifications, equivalent replacements, improvements, and the like made within the spirit and principle of the present disclosure shall be included within the scope of protection of the present disclosure.

1. A light-emitting assembly, comprising:
a base substrate having a first surface and a second surface;
a color conversion layer disposed on the first surface of the base substrate;
a light-emitting unit disposed on a side of the color conversion layer away from the base substrate, wherein the light-emitting unit emits light for exiting the second surface of the base substrate after passing through the color conversion layer; and
a light-shielding structure having a light-shielding region and a plurality of first hollowed-out regions, wherein an orthographic projection of each of the first hollowed-out regions on the base substrate is at least partially overlapped with a light-emitting region of the light-emitting unit, and the first hollowed-out regions is used for the light emitted from the light-emitting unit to transmit, and the light-shielding structure is configured to absorb light irradiating to the light-shielding region;
wherein at least one of the first surface and the second surface is provided with a light-dimming portion configured to change a propagation direction of light.

2. The light-emitting assembly according to claim 1, wherein the light-dimming portion comprises a light-extraction grating;
wherein an orthographic projection of the light-extraction grating on the base substrate is at least partially overlapped with an orthographic projection of the light-shielding region on the base substrate, the light-extraction grating is configured to transmit the light emitted from the light-emitting unit, and the light-shielding structure is capable of absorbing light transmitted from the light-extraction grating.

3. The light-emitting assembly according to claim 2, wherein the light-shielding structure is disposed between the first surface of the base substrate and the light-emitting unit, and the light-extraction grating is disposed between the first surface of the base substrate and the light-shielding structure; and the light-dimming portion further comprises a reflective layer;
wherein the reflective layer is disposed on the second surface of the base substrate, and an orthographic projection of the reflective layer on the base substrate is at least partially overlapped with the orthographic projection of the light-shielding region on the base substrate, and the reflective layer is configured to reflect light irradiated to the reflective layer to the light-extraction grating.

4. The light-emitting assembly according to claim 2, wherein the light-shielding structure comprises a first light-shielding portion disposed between the first surface of the base substrate and the light-emitting unit, and a second light-shielding portion disposed on the second surface of the base substrate, wherein an orthographic projection of the second light-shielding portion on the base substrate covers an orthographic projection of the first light-shielding portion on the base substrate; and
the light-extraction grating is disposed between the second surface of the base substrate and the second light-shielding portion, and the light emitted from the light-emitting unit is absorbed by the second light-shielding portion after transmitting the light-extraction grating.

5. The light-emitting assembly according to claim 2, wherein the light-emitting assembly comprises a plurality of light-emitting units, wherein the light-emitting units emit light of a same color, and colors emitted from the plurality of light-emitting units after passing through the color conversion layer comprise a first color, a second color, and a third color that are different from each other; and the light-extraction grating comprises:
a first grating, configured to transmit light of the first color, wherein an orthographic projection of the first grating on the base substrate surrounds a light-emitting region of a first light-emitting unit in the plurality of light-emitting units, and a color of light emitted from the first light-emitting unit after passing through the color conversion layer is the first color;
a second grating, configured to transmit light of the second color, wherein an orthographic projection of the second grating on the base substrate surrounds a light-emitting region of a second light-emitting unit in the plurality of light-emitting units, and a color of light emitted from the second light-emitting unit after passing through the color conversion layer is the second color; and
a third grating, configured to transmit light of the third color, wherein an orthographic projection of the third grating on the base substrate surrounds a light-emitting region of a third light-emitting unit in the plurality of light-emitting units, and a color of the light emitted from the third light-emitting unit after passing through the color conversion layer is the third color.

6. The light-emitting assembly according to claim 5, wherein colors emitted from the plurality of light-emitting units are all of the third color; and the light-extraction grating further comprises a fourth grating;
wherein an orthographic projection of the fourth grating on the base substrate surrounds light-emitting regions of the plurality of light-emitting units, and the fourth grating is configured to transmit light of the third color.

7. The light-emitting assembly according to claim 1, wherein a groove structure is arranged in at least one of the first surface and the second surface;
wherein the light-dimming portion is disposed in the groove structure, the light-dimming portion is configured to reflect light irradiated to the light-dimming portion to a region where an orthographic projection of the light-emitting region of the light-emitting unit is disposed on the base substrate, or the light-dimming portion is configured to absorb the light irradiated to the light-dimming portion; and
the groove structure surrounds the light-emitting region of the light-emitting unit.

8. The light-emitting assembly according to claim 7, wherein the light-emitting assembly comprises a plurality of light-emitting units, wherein the light-emitting units emit light of a same color, and colors emitted from the plurality of light-emitting units after passing through the color conversion layer comprise a first color, a second color, and a third color that are different from each other; the groove structure comprises:
a plurality of first annular grooves, wherein each of the first annular grooves surrounds a light-emitting region of one of the light-emitting units; and
a second annular groove, wherein the second annular groove surrounds light-emitting regions of the plurality of light-emitting units; and
the light-dimming portion comprises:
a plurality of first light-dimming portion, wherein each of the first light-dimming portions is disposed in one of the first annular grooves, a material of the first light-dimming portion is a reflective material or a light-absorbing material; and
a second light-dimming portion, wherein the second light-dimming portion is disposed in the second annular groove, and a material of the second light-dimming portion is a light-absorbing material.

9. The light-emitting assembly according to claim 8, wherein the second annular groove comprises a plurality of sub-annular grooves, wherein a depth of each of the sub-annular grooves is negatively correlated with a distance between the sub-annular groove and the light-emitting unit; and
the second light-dimming portion comprises a plurality of sub-light-dimming portions, wherein each of the sub-light-dimming portions is disposed in one of the sub-annular grooves.

10. The light-emitting assembly according to claim 9, wherein the plurality of sub-annular grooves comprises a plurality of first sub-annular grooves and a plurality of second sub-annular grooves;
wherein the plurality of first sub-annular grooves are disposed in the first surface, the plurality of second sub-annular grooves are disposed in the second surface, the plurality of first sub-annular grooves and the plurality of second sub-annular grooves are staggered, and a sum of a depth of one of the first sub-annular grooves and a depth of one of the second sub-annular grooves is less than a thickness of the base substrate; and
the second light-dimming portion comprises a plurality of first sub-dimming portions and a plurality of second sub-dimming portions, wherein each of the first sub-dimming portions is disposed in one of the first sub-annular grooves, and each of the second sub-dimming portions is disposed in one of the second sub-annular grooves.

11. The light-emitting assembly according to claim 7, wherein both the first annular grooves and the second annular groove are continuous grooves .

12. The light-emitting assembly according to claim 7, further comprising a light-absorbing portion, wherein the light-absorbing portion at least covers a side edge of the base substrate, and a material of the light-absorbing portion is a light-absorbing material.

13. The light-emitting assembly according to claim 1, further comprising a color film layer disposed between the base substrate and the color conversion layer;
wherein the color film layer comprises a plurality of color film patterns, the color conversion layer comprises a plurality of color conversion patterns and a plurality of light-transmitting patterns, wherein each of the plurality of color film patterns corresponds to one target pattern in the plurality of color conversion patterns and the plurality of light-transmitting patterns; and
the light-emitting assembly further comprises a retaining wall structure; wherein the retaining wall structure has a plurality of second hollowed-out regions, wherein the plurality of second hollowed-out regions are in one-to-one correspondence with the plurality of first hollowed-out regions, and an orthographic projection of each of the second hollowed-out regions on the base substrate is at least partially overlapped with an orthographic projection of a corresponding first hollowed-out region on the base substrate;
wherein each of the color film patterns is disposed in one of the first hollowed-out regions, and the target pattern corresponding to the color film pattern is disposed in the second hollowed-out region corresponding to the first hollowed-out region.

14. The light-emitting assembly according to claim 1, wherein the light-emitting unit comprises a first electrode, a second electrode, and a light-emitting layer connected to the first electrode and the second electrode; and the light-emitting assembly further comprises a driving unit disposed on a side of a plurality of light-emitting units away from the base substrate;
wherein the driving unit comprises a third electrode, a fourth electrode, and a driving circuit, wherein both the third electrode and the fourth electrode are connected to the driving circuit, and the third electrode is connected to the first electrode, and the fourth electrode is connected to the second electrode.

15. A display panel, comprising a display backplane, and a plurality of light-emitting assemblies-as that are disposed on a side of the display backplane and arranged in an array;
wherein the display backplane is configured to provide a drive signal for the light-emitting assemblies to drive the light-emitting assemblies to emit light; and
the each of the plurality of light-emitting assemblies comprises:
a base substrate having a first surface and a second surface;
a color conversion layer disposed on the first surface of the base substrate;
a light-emitting unit disposed on a side of the color conversion layer away from the base substrate, wherein the light-emitting unit emits light for exiting the second surface of the base substrate after passing through the color conversion layer; and
a light-shielding structure having a light-shielding region and a plurality of first hollowed-out regions, wherein an orthographic projection of each of the first hollowed-out regions on the base substrate is at least partially overlapped with a light-emitting region of the light-emitting unit, and the first hollowed-out regions is used for the light emitted from the light-emitting unit to transmit, and the light-shielding structure is configured to absorb light irradiating to the light-shielding region;
wherein at least one of the first surface and the second surface is provided with a light-dimming portion configured to change a propagation direction of light.

16. The light-emitting assembly according to claim 7, wherein each of the first annular grooves comprises a plurality of first dotted grooves, an arrangement of the plurality of first dotted grooves being annular; and
the second annular groove comprises a plurality of second dotted grooves, and an arrangement of the plurality of second dotted grooves being annular.

17. The display panel according to claim 15, wherein the light-dimming portion comprises a light-extraction grating;
wherein an orthographic projection of the light-extraction grating on the first base substrate is at least partially overlapped with an orthographic projection of the light-shielding region on the first base substrate, the light-extraction grating is configured to transmit the light emitted from the light-emitting unit, and the light-shielding structure is capable of absorbing light transmitted from the light-extraction grating.

18. The display panel according to claim 17, wherein the light-shielding structure is disposed between the first surface of the base substrate and the light-emitting unit, and the light-extraction grating is disposed between the first surface of the base substrate and the light-shielding structure; and the light-dimming portion further comprises a reflective layer;
wherein the reflective layer is disposed on the second surface of the base substrate, and an orthographic projection of the reflective layer on the base substrate is at least partially overlapped with the orthographic projection of the light-shielding region on the base substrate, and the reflective layer is configured to reflect light irradiated to the reflective layer to the light-extraction grating.

19. The display panel according to claim 17, wherein the light-shielding structure comprises a first light-shielding portion disposed between the first surface of the base substrate and the light-emitting unit, and a second light-shielding portion disposed on the second surface of the second base substrate, wherein an orthographic projection of the second light-shielding portion on the base substrate covers an orthographic projection of the first light-shielding portion on the base substrate; and
the light-extraction grating is disposed between the second surface of the base substrate and the second light-shielding portion, and the light emitted from the light-emitting unit is absorbed by the second light-shielding portion after transmitting the light-extraction grating.

20. The display panel according to claim 17, wherein the light-emitting assembly comprises a plurality of light-emitting units, wherein the light-emitting units emit light of a same color, and colors emitted from the plurality of light-emitting units after passing through the color conversion layer comprise a first color, a second color, and a third color that are different from each other; and the light-extraction grating comprises:
a first grating, configured to transmit light of the first color, wherein an orthographic projection of the first grating on the base substrate surrounds a light-emitting region of a first light-emitting unit in the plurality of light-emitting units, and a color of light emitted from the first light-emitting unit after passing through the color conversion layer is the first color;
a second grating, configured to transmit light of the second color, wherein an orthographic projection of the second grating on the base substrate surrounds a light-emitting region of a second light-emitting unit in the plurality of light-emitting units, and a color of light emitted from the second light-emitting unit after passing through the color conversion layer is the second color; and
a third grating, configured to transmit light of the third color, wherein an orthographic projection of the third grating on the base substrate surrounds a light-emitting region of a third light-emitting unit in the plurality of light-emitting units, and a color of the light emitted from the third light-emitting unit after passing through the color conversion layer is the third color.
